(19) United States
(12) Patent Application Publication
(10) Pub. No.: US 2024/0072464 A1
(43) Pub. Date: Feb. 29, 2024

(54) ELECTRICAL PLUG-IN CONNECTION AND PRINTED CIRCUIT BOARD ARRANGEMENT

(71) Applicant: ROSENBERGER HOCHFREQUENZTECHNIK GMBH & CO.KG, Fridolfing (DE)

(72) Inventors: Tobias Stadler, Fridolfing (DE); Bernhard Aicher, Fridolfing (DE)

(21) Appl. No.: 18/272,202

(22) PCT Filed: Jul. 12, 2021
(86) PCT No.: PCT/EP2021/069297

§ 371 Date: Jul. 13, 2023

(30) Foreign Application Priority Data
Jan. 14, 2021 (EP) 21151507.7

(51) Int. Cl. H01R 12/71; H01R 13/10

(52) U.S. Cl. CPC H01R 12/714; H01R 13/10

(57) ABSTRACT

The present invention relates to an electrical plug-in connection (2). The present invention also relates to a printed circuit board arrangement (1). An electrical plug-in connection. (2) has a plug-in connector (8) and a mating plug-in connector (9). The plug-in connector (8) contains a contact element (10), whereas the mating plug-in connector (9) contains a contact body (11) which comprises a plurality of electrically interconnected contact regions (14) which are each deformable. The contact regions (14) are arranged with respect to one another in such a way that different insertion regions (17) for inserting the contact element (10) into the contact, body (11) can be formed in the contact body (11). In each case one of the contact regions (14) is arranged between at least two of the insertion regions (17) in the contact body (11) in at least one direction which nun orthogonally to a longitudinal axis (16) of the contact element (10). The contact regions (14) each adjoining the respective insertion region (17) are deformed by the contact element (10) inserted into the respective insertion region (17) in such a way that an electrical contact and a mechanical connection can be established between the plug-in connector (8) and the mating plug-in connector (9).

The present patent application claims the priority of European patent application no. 21 151 507, the content of which is fully incorporated herein by reference.

### FIELD OF THE INVENTION

The present invention relates to an electrical plug-in connection.

The present invention also relates to a printed circuit board arrangement.

### TECHNICAL BACKGROUND

In electrical devices and systems, electronic components and electronic circuits are mechanically fastened on a printed circuit board (PCB) and are electrically connected to one another. On account of the complexity of the electronics, they are distributed among a plurality of printed circuit boards. Therefore, electrical connections, so-called board-to-board connections, are required between the printed circuit boards for the purpose of transmitting signals and electrical potentials.

If DC signals or DC potentials or low-frequency signals or low-frequency electrical potentials are involved, simple lines or cables, for example ribbon cables, plug-in connectors or printed circuit boards are typically used here. In contrast, if high-frequency components and high-frequency circuits are located on the printed circuit boards, high-frequency connections, preferably coaxial high-frequency connections, need to be provided between the printed circuit boards.

Coaxial board-to-board connections between printed circuit boards arranged in a parallel manner are preferably implemented in the form of three-part high-frequency plug-in connectors. In this case, each printed circuit board is respectively electrically and mechanically connected to a coaxial plug-in connector. The electrical and mechanical connection between these two coaxial plug-in connectors is effected via an interposed coaxial adapter (“bullet”). Interposing the coaxial adapter makes it possible to compensate for a variable distance and an axial and rotational offset between the two printed circuit boards within a particular tolerance range.

Coaxial plug-in connectors and coaxial adapters each generally have an inner conductor, an outer conductor and an insulation element which is located between the inner conductor and the outer conductor and electrically insulates the inner conductor from the outer conductor. In the case of a multiplicity of high-frequency plug-in connections between the two printed circuit boards, this structure was recently simplified for cost reasons:

In this case, the outer conductor of each high-frequency plug-in connection is replaced with a common electrically conductive plate, preferably a metal plate, which is arranged between the two printed circuit boards and can also be used as the housing of the printed circuit board arrangement. The metal plate respectively has a through-hole for each high-frequency plug-in connection. An inner conductor connection is arranged inside the through-hole concentrically with respect to the inner wall of the through-hole. The inner conductor connection may be spaced apart from the metal plate used as the outer conductor connection by an insulation element that surrounds the inner conductor connection. Alternatively, the electrical insulation between the inner conductor and the outer conductor may be achieved by providing a suitably dimensioned air gap between the inner conductor and the outer conductor. Instead of a metal plate having a number of through-holes corresponding to the number of high-frequency plug-in connections, a metal sleeve fastened and arranged between the printed circuit boards may be respectively used as the outer conductor for each high-frequency plug-in connection. This means that a coaxial structure is respectively implemented for each high-frequency plug-in connection and ensures that a high-frequency signal is transmitted with a sufficient signal quality.

As part of the further advancing cost reduction, the structure and the installation of the high-frequency plug-in connection, in particular—but not exclusively—a high-frequency plug-in connection between two printed circuit boards, should be simplified without impairing the high-frequency signal transmission quality. In particular, the structure of the inner conductor connection should be simplified in this case, that is to say the number of components of the inner conductor connection should be reduced further.

Furthermore, stricter requirements in the bridging of geometrical deviations between the assemblies to be connected to one another, for example printed circuit boards, that is to say a greater tolerance range in the distance between the assemblies or printed circuit boards and in the axial and rotational offset between the assemblies or printed circuit boards, should be managed with such a high-frequency plug-in connection.

With respect to the technological background relating to printed circuit board plug-in connections, reference is made, by way of example, to US 2013/0083379 A1 which discloses a multi-pole printed circuit board plug-in connection, and to WO 2010/075246 A1 which relates to an arrangement comprising a plurality of coaxial printed circuit board plug-in connectors for multi-pole signal transmission. In addition, reference is also made to EP 3 550 669 A1 which relates to a coaxial high-frequency plug-in connection.

### SUMMARY OF THE INVENTION

Against this background, the present invention is based on the object of simplifying the structure and the installation of an electrical plug-in connection, in particular between electrical assemblies such as printed circuit boards, whilst retaining the signal quality required for high-frequency transmission, and, at the same time, of meeting increased requirements with respect to geometrical deviations, for example between the assemblies or printed circuit boards.

Filially, the present invention is based on the object of providing a printed circuit board arrangement which can be easily installed and meets the increased mechanical requirements, while maintaining the high-frequency transmission properties.

According to the invention, this object is achieved by means of the invented electrical plug-in connection and by means of the invented printed circuit board arrangement.

Accordingly, provision is made for:
An electrical plug-in connection having
an electrical plug-in connector and
an electrical mating plug-in connector,
wherein the plug-in connector has a contact element,
wherein the mating plug-in connector has a contact body comprising a plurality of contact regions which are connected to one another and are each deformable, wherein the contact regions are electrically connected to one another,
wherein the contact regions are arranged with respect to one another in such a manner that different insertion regions for inserting the contact element into the contact body can be formed in the contact body,
wherein one of the contact regions is respectively arranged between different insertion regions (preferably between at least two of the insertion regions) in the contact body in at least one direction which runs orthogonally to a longitudinal axis of the contact element, and
wherein the contact regions respectively adjoining the respective insertion region are deformed by the contact element inserted in the respective insertion region in such a manner that electrical contact and a mechanical connection can be established between the plug-in connector and the mating plug-in connector.

The contact regions are preferably arranged with respect to one another in such a manner that the insertion regions are formed in the contact body thereby, in particular between adjacently arranged contact regions.

All contact regions of the contact body are preferably electrically connected to one another. One, a plurality of or all of the contact regions may also be mechanically connected to one another; in particular, contact regions which are adjacent to one another may be directly electrically and mechanically connected to one another—for example even formed in one piece with one another. However, the contact regions may also be components which are independent of one another or may have multiple parts and may be electrically connected to one another indirectly via further components and/or via the contact body, for example.

The plug-in connector preferably has precisely one contact element and no further contact elements or a plurality of contact elements which are electrically (and mechanically) connected to one another.

The proposed electrical plug-in connection can preferably be used to establish an electrical connection between a first electrical assembly, preferably the first electrical printed circuit board which is also mentioned below, and a second electrical assembly, preferably the second electrical printed circuit board which is also mentioned below. However, although the electrical plug-in connection is advantageously suitable for electrically connecting two electrical assemblies and is very particularly advantageous for establishing an electrical connection between two electrical printed circuit boards, the proposed electrical plug-in connection may be suitable, in principle, for any desired electrical applications (for example also for adapter applications or even for connecting two electrical cables or one electrical cable to an electrical assembly). For the sake of easier understanding, the invention is described below substantially for the application as a printed circuit board plug-in connection—however, this should not be understood as being restrictive.

In one configuration of the plug-in connection, provision may be made for the contact element to be able to be electrically and mechanically connected to a first electrical assembly, preferably a first electrical printed circuit board.

In one configuration of the plug-in connection, provision may be made for the contact body to be able to be electrically and mechanically connected to a second electrical assembly, preferably a second electrical printed circuit board.

In one configuration of the plug-in connection, provision may be made for the plug-in connection to have a rigid connecting element which can be arranged between two electrical assemblies (in particular can be fastened to at least one or to both assemblies), preferably can be arranged or fastened between two electrical printed circuit boards. The rigid connecting element may preferably have a through-hole which is used by the connecting element to enclose the contact element and the contact body.

The invention also relates to:

An assembly arrangement, in particular a printed circuit board arrangement, comprising
at least one first assembly, preferably a printed circuit board,
at least one second assembly, preferably a printed circuit board, and
at least one electrical plug-in connection according to the embodiments above and below,
wherein the assemblies or printed circuit boards are arranged in a manner running in different planes with respect to one another,
wherein the respective electrical plug-in connection respectively electrically connects the assemblies or printed circuit boards to one another.

In one configuration, a rigid connecting element is arranged between the assemblies or printed circuit boards and electrically connects the first assembly or the first printed circuit board and the second assembly or the second printed circuit board to one another. The connecting element may have a through-hole in order to enclose the at least one electrical plug-in connection.

The contact regions are preferably arranged with respect to one another in such a manner that the insertion regions are formed in the contact body thereby, in particular between adjacently arranged contact regions.

An electrical plug-in connection between at least two printed circuit boards has a plug-in connector and a mating plug-in connector. The plug-in connector contains a contact element, whereas the mating plug-in connector contains a contact body. If the contact element is respectively electrically and mechanically connected to one printed circuit board and the contact body is respectively electrically and mechanically connected to the other printed circuit board and if electrical contact and a mechanical connection can be achieved between the contact element and the contact body, a two-part inner conductor connection is therefore implemented between the two printed circuit boards.

If the contact body has a plurality of contact regions which are electrically connected to one another, are each deformable and are arranged with respect to one another in such a manner that different insertion regions for inserting the contact element into the contact body can be formed in the contact body, contact between the contact element and the contact body is possible for different lateral impingement positions of the contact element on the contact body. An axial offset between the assembly/printed circuit board connected to the contact element and the assembly/printed circuit board connected to the contact body can therefore be overcome.

If the contact body with its individual contact regions has a circular profile according to the prior art, as is clear from FIG. 1A, the insertion regions of the contact element which are each illustrated using hatching in FIG. 1A are possible inside the circular contact body, for example. No contact region of the contact body is arranged between different insertion regions. Only a maximum distance D₁ between different insertion regions, which is less than the diameter of the circular contact body, is therefore possible.

In contrast, if, according to the invention, a contact region is arranged between the different insertion regions of the contact element in the contact body in at least one direction which runs orthogonally to a longitudinal axis of the contact element, it is advantageously possible to achieve an increased distance between different insertion regions of the inner conductor contact element in the contact body, if a plurality of contact regions of the contact body are preferably arranged at a distance from one another in at least one direction, the distance between different insertion regions can be additionally increased. According to FIG. 1B, insertion regions for the contact element are illustrated, by way of example, between the individual circular contact regions of the contact body which are arranged concentrically with respect to one another. This makes it possible to achieve a distance D2 between different insertion regions of the contact element in the contact body which is increased in comparison with the distance D₁. An axial offset between the two printed circuit boards can be bridged to a greater extent by suitably arranging the individual contact regions in the contact body.

The contact regions respectively adjoining the respective insertion region are deformed by the contact element inserted in the respective insertion region in such a manner that good electrical contact and a good mechanical connection can be established between the plug-in connector and the mating plug-in connector.

The contact element is preferably a pin-shaped contact element, that is to say a substantially cylindrical contact element. Such a cylindrical contact element can be produced most easily and most easily complies with the coaxiality with respect to a through-hole in a metal plate or metal sleeve used as the outer conductor, which coaxiality is required for high-frequency transmission. In the case of an accordingly shaped through-hole in the metal plate or in the metal sleeve, any other technically sensible cross-sectional profile, for example a square or an elliptical cross-sectional profile, is also conceivable for the contact element.

The contact element can be inserted in the contact body by way of a longitudinal-side end which is referred to as the first end of the contact element below.

The contact body comprising a plurality of contact regions which are electrically connected to one another and are each deformable has a more complex structure than the contact element. In the non-contacted state, the contact body is preferably arranged axially adjacent to the contact element. The end surface of the contact body at the first end of the contact body may be used as the impingement surface for the contact element. In the contacted state, an axial section of the contact element is axially inserted into the contact body.

The basic shape of the contact element is preferably cylindrical. However, any other suitable cross-sectional profile, for example a square or elliptical cross-sectional profile, is also conceivable. In order to be able to achieve a greater axial offset between the two printed circuit boards by establishing contact between the contact element and the contact body, the size of the end surface of the contact body should preferably be designed as a multiple of the diameter of that region of the contact element which is inserted into the contact body.

In this case, a diameter ratio between the end surface of the contact body and that region of the contact element which is inserted into the contact body of preferably at least 2.5, more preferably at least four, and very particularly preferably at least five, should be implemented.

In order to form different insertion regions for the contact element in the contact body, openings, gaps, recesses and/or holes may be provided between the individual contact regions at the first end of the contact body in the direction of the longitudinal axis of the contact element. The contact element may be respectively inserted into the contact body in the individual openings, gaps, recesses and/or holes. The individual openings, gaps, recesses and/or holes may be formed, on the one hand, in such a manner that they each form only a single insertion region for the contact element. Alternatively, the openings, gaps, recesses and/or holes may also be designed in such a manner that they each provide a plurality of adjacent insertion regions, under certain circumstances a multiplicity of insertion regions adjacent to one another, for the contact element.

The cross section of the openings, gaps, recesses and/or holes should preferably be designed in such a manner that the contact element can be inserted into the contact body and, at the same time, reliable contact between the contact element and at least one contact region of the contact body is ensured.

The individual openings, gaps, recesses and/or holes at the first end of the contact body may each also be formed only over a section of the longitudinal extent of the contact body. In this case, the contact element can be inserted into the contact body and can make contact with the contact body only in a section of the longitudinal extent of the contact body.

Alternatively, the individual openings, gaps, recesses and/or holes may be formed over the entire longitudinal extent of the contact body, that is to say from a first end of the contact body to an opposite, second end of the contact body, and may therefore each conduct the contact element through the entire contact body in the direction of the longitudinal axis. A greater distance between the two printed circuit boards can be bridged with such a formation of the individual openings, gaps, recesses and/or holes.

With regard to good contact, the contact element and the contact body with its individual contact regions may be produced from a metallic material having good electrical conductivity, for example brass or copper. In order to minimize the transfer impedance between the contact element and the individual contact regions of the contact body, the associated contact regions of the contact element and of the contact body may be coated with a coating material which has higher electrical conductivity than the base material, for example gold or silver.

In order to achieve a good contact pressure between the contact element and the individual contact regions of the contact body and therefore reliable contact, the individual contact regions of the contact body should be designed to be deformable. For the deformability of the contact regions, they should be designed to be sufficiently elastic. The elastic restoring force of the deformed contact region produces a sufficient contact pressure between the contact element and the contact body. The elasticity of the individual contact regions is preferably achieved by means of a suitable geometrical formation of the individual contact regions themselves and/or of the connection or suspension between the individual contact regions and a contact frame. In this case, the elasticity of the individual contact regions can be achieved, for example, by forming the contact regions as contact larnellae, that is to say as thin contact plates or thin contact disks, or as contact springs, in particular as contact spring arms. The elastic connection or the elastic suspension of the individual contact regions inside a contact frame can be respectively effected via thin junctions, for example in the sense of a film hinge. An exemplary, specific elastic formation of the individual contact regions of the contact body is also explained in detail further below.

Advantageous configurations and developments emerge from the further subclaims and from the description with reference to the figures of the drawing.

It goes without saying that the features mentioned above and the features yet to be explained below can be used not only in the respectively stated combination, but also in other combinations or alone, without departing from the scope of the present invention.

The contact regions of the contact body which each adjoin the individual insertion regions may preferably form a contact surface with the contact element. The contact surface should respectively be dimensioned in such a manner that a transfer impedance sufficient for making contact is ensured.

Alternatively, the individual contact region of the contact body may also be in the form only of an individual contact line or a plurality of individual contact lines. The individual contact line may respectively run in the circumferential direction and/or in the direction of the longitudinal axis of the contact element. In this case, the longitudinal extent of the individual contact line may be implemented in a partially or fully circumferential manner over the circumference with which contact is to be made or over that extent of the longitudinal axis of the contact element with which contact is to be made. Any desired regular and irregular courses of a contact line are conceivable. With regard to a sufficient transfer impedance between the contact element and the contact body, the width of the contact line should be dimensioned to be sufficiently large.

In one preferred embodiment of the electrical plug-in connection, the individual contact regions each have, in a direction orthogonal to the longitudinal axis of the contact element, an extent which is less than, preferably a multiple less than, an extent of the contact element in the same direction.

Such a preferred design minimizes the impingement of the contact element on an end surface of a contact region of the contact body and therefore minimizes impeded insertion of the contact element into an insertion region of the contact body.

At its first end, the contact element may have a longitudinal portion having a preferably constant diameter, that is to say a cylindrical longitudinal portion, which is referred to as the first longitudinal portion below. When the contact element is in contact with the contact body, the first longitudinal portion of the contact element is inserted in an insertion region of the contact body. The first longitudinal portion may be inserted in the insertion region either completely or only partially, that is to say only an axial section of the first longitudinal portion. The axial extent of the first longitudinal portion that is located in the insertion region depends, on the one hand, on the distance between the two printed circuit boards and, on the other hand, on the geometrical dimensions of the contact element and of the contact body. The insertion region inside the contact body into which the contact element is inserted in each case results from the respective impingement position of the contact element on the end surface of the contact body, that is to say from the relative lateral position of the longitudinal axis of the contact element with respect to the contact body. The individual contact regions of the contact body are each arranged with respect to one another in such a manner that an insertion region is respectively formed in the contact body for each possible relative lateral position of the longitudinal axis of the contact element with respect to the contact body and is adjoined by at least one contact region of the contact body. Electrical contact and a mechanical connection between the contact element and at least one contact region of the contact body therefore result for each relative position of the contact element with respect to the contact body.

In one preferred embodiment of the electrical plug-in connection, a further longitudinal portion having a tapering diameter in the direction of the end of the contact element may be connected between the first longitudinal portion and the first end of the contact element. This further longitudinal portion of the contact element is referred to as the second longitudinal portion below.

In addition to the first end, the contact element has a second end which is located in the region of the connection between the plug-in connector and the printed circuit board.

As a result of the tapering of the diameter in the second longitudinal portion of the contact element, simple and reliable insertion of the contact element into the nearest insertion region of the contact body is additionally improved for any desired relative lateral position of the contact element with respect to the contact body.

The tapering of the diameter in the second longitudinal portion of the contact element may preferably be conical. Alternatively, the tapering may be spherical, that is to say rounded, concavely curved or convexly curved. In special fields of application, a plurality of contact tips may also be formed in the second longitudinal portion of the contact element.

In order to completely insert the first longitudinal portion of the contact element into an insertion region of the contact body, the longitudinal extent of the insertion regions preferably corresponds at least to the longitudinal extent of the first longitudinal portion of the contact element. If a second longitudinal portion adjoins the first longitudinal portion in the contact element, the longitudinal extent of the insertion regions preferably corresponds at least to the longitudinal extent of the first and second longitudinal portions of the contact element.

In addition or as an alternative to a contact element having a second longitudinal portion with a tapering diameter, the contact regions of the contact body may each have, in a first cross-sectional portion at a first end of the respective contact region that is directed toward the plug-in connector, a cross-sectional profile tapering to the first end. The contact element can therefore additionally be inserted into the nearest insertion region of the contact body in a simpler and more reliable manner.

In analogy to the diameter tapering ill the second longitudinal portion of the contact element, a conical, spherical, concavely curved or convexly curved cross-sectional profile can be selected as the tapering cross-sectional profile in the individual contact regions.

The axial distance between the plug-in connector and the mating plug-in connector may determine the extent of electrical contact between the contact element and the contact body:

In the case of contact regions which extend over the entire longitudinal extent of the contact body, for example in the case of the contact lamellae yet to be described, depending on the axial distance between the plug-in connector and the mating plug-in connector, a section of the first longitudinal portion makes contact with the contact body with a respective axial length.

In the case of contact regions which extend only over a section of the entire longitudinal extent of the contact body, for example in the case of the contact wire mesh yet to be described, depending on the axial distance between the plug-in connector and the mating plug-in connector, a section of the first longitudinal portion makes contact with the contact body in a respective axial position inside the first longitudinal portion.

In one preferred embodiment of the invention, the individual contact regions may be arranged with respect to one another in the contact body in a regular structure. The insertion regions for the contact element which are formed between the individual regularly arranged contact regions are therefore likewise arranged in a regular manner. In this case, the regular structure may be formed in a direction orthogonal to the direction of the longitudinal axis of the contact element or alternatively in two directions orthogonal to the direction of the longitudinal axis, that is to say in a grid. The regular structure of the individual contact regions inside the contact body enables a mechanically stable structure of the contact body. This is achieved, in particular, by virtue of the fact that the individual contact regions are connected in the best possible manner to an outer contact frame belonging to the contact body. The individual contact regions in the contact body are additionally mechanically stabilized by arranging the individual contact regions in a particular grid.

The individual contact regions of the contact body may each be arranged inside individual contact lamellae. The contact lamellae are each thin contact disks or thin contact plates which are preferably arranged parallel to one another at a particular grid spacing. The preferably elongate contact lamellae are each oriented, in terms of their longitudinal extent, in a direction orthogonal to the longitudinal axis of the contact element. Their two longitudinal ends are preferably connected to a contact frame of the contact body that surrounds all contact lamellae.

Alternatively, the preferably elongate contact lamellae may each be connected, at their transverse end directed toward the printed circuit board, to a contact frame or a contact plate, which is formed on the underside of the contact body, or directly to a contact surface on the printed circuit board. The individual contact lamellae are preferably connected to the contact frame, to the contact plate or to the contact surface in the region of one longitudinal end or both longitudinal ends of the individual contact lamellae in order to make it possible to deform the contact lamella between the two longitudinal ends when inserting the contact element between the individual contact lamellae.

The individual contact lamellae are each preferably planar along their longitudinal extent. Alternatively, an undulating shape, an angled shape or a zigzag shape of the individual contact lamellae along their longitudinal extent is also possible.

If the individual contact regions are arranged in a particular grid with respect to one another, they are preferably formed inside individual contact wires or contact bars. These individual contact wires or contact bars are each arranged in a cross-grid with respect to one another. The individual contact wires or contact bars are preferably connected, at their two longitudinal ends, to a contact frame which belongs to the contact body and surrounds the contact wires or contact bars. The contact wires or contact bars are preferably not fixed with respect to one another at the individual intersection points or regions, in order to make it possible to deform the individual contact wires or contact bars when inserting the contact element into the contact body. The pattern of the cross-grid may be constructed from individual squares or individual rhombi by suitably arranging the contact wires or contact bars with respect to one another. The contact regions of the contact wires or contact bars typically result in individual contact lines in a manner corresponding to the diameter of the contact wire or contact bar.

In a further embodiment of the invention, the contact regions of the contact body may be arranged along a bent contact lamella. This bent contact lamella may preferably be spirally shaped and arranged in a plane inside the contact body that is oriented orthogonally to the longitudinal axis of the contact element. With regard to good deformability of the spiral contact lamella, it is preferably connected, only at its longitudinal end that is positioned radially on the outside, to a contact surface or a contact region of the printed circuit board or the contact frame.

Alternatively, the individual contact regions of the contact body may be arranged in a plurality of respectively circular contact lamellae. These circular contact lamellae each have a different diameter and are arranged concentrically to one another in a plane inside the contact body that is oriented orthogonally to the longitudinal axis of the contact element. Owing to the deformability of the circular contact lamellae, the contact lamellae may each be connected, at their transverse end directed toward the printed circuit board, only in up to two contact regions or contact points of the printed circuit board or the contact frame. In addition to individual circular contact lamellae, elliptical contact lamellae are alternatively also conceivable.

Finally, in a further embodiment of the invention, the individual contact regions of the contact body may each be arranged in an irregular manner with respect to one another. This may be, in particular, an electrically conductive wire mesh which is three-dimensionally braided. The three-dimensionally braided wire mesh is preferably pressed to form a compressed contact body in order to suitably define the average distance between the individual wires in all regions of the compressed contact body. The average distance between the individual wires can be defined by the pressing in such a manner that, on the one hand, insertion regions for the contact element can be formed between the individual wires of the wire mesh and, on the other hand, sufficient contact regions for good electrical contact and a good mechanical connection between the wire mesh and the contact element can be implemented. The contact regions of the wire mesh typically result in individual contact lines in a manner corresponding to the wire thickness of the wire mesh.

The invention also relates to a printed circuit board arrangement comprising at least one first printed circuit board and one second printed circuit board, wherein the printed circuit boards are arranged in a manner running parallel to one another in different planes.

The printed circuit board arrangement preferably comprises two printed circuit boards. However, a printed circuit board arrangement having more than two printed circuit boards, for example three printed circuit boards, four printed circuit boards and more printed circuit boards, is also conceivable.

Owing to tolerances, the individual printed circuit boards may also have a slight deviation from the parallel arrangement. A tolerance-related deviation of the parallelism of, for example, up to 10°, preferably of up to 5°, and particularly preferably of up to 4°, should therefore be understood as being covered by the term “parallel”.

Two printed circuit boards which are each arranged opposite one another may be arranged with an axial offset with respect to one another. In this case, axial offset is understood as meaning the fact that contacts which are each arranged on the two printed circuit boards and are to be electrically connected to one another via a board-to-board connection are not on a common connecting straight line which is oriented perpendicular to the two printed circuit board planes. Rather, in the case of an axial offset, the two contacts are on two connecting straight lines which are at a distance from one another.

Two printed circuit boards which are each arranged opposite one another may also be arranged in a rotationally offset manner with respect to one another. In this case, rotational offset is understood as meaning the fact that contacts which are each arranged on the two printed circuit boards and are to be electrically connected to one another via a board-to-board connection are on two parallel connecting straight lines which are arranged at a distance from one another at a particular angle of rotation in relation to a parallel axis of rotation.

Finally, the two printed circuit boards may be at a distance from one another in a deviation from a target distance.

Furthermore, a rigid connecting element which electrically connects the first printed circuit board and the second printed circuit board to one another may be arranged between the printed circuit boards in the printed circuit board arrangement according to the invention. The rigid connecting element is preferably a plate which is arranged between the two printed circuit boards and is preferably mechanically connected to the two printed circuit boards by means of a screw connection. The rigid connecting element may be produced from an electrically conductive material, preferably from a metal, and may electrically connect the two printed circuit boards. The electrically conductive rigid connecting element therefore makes contact in each case with a contact surface, preferably a ground contact surface, on the two printed circuit boards. As a result of the ground contact, the rigid connecting element may be used as an outer conductor or as a shield for each high-frequency connection respectively formed between the two printed circuit boards.

The connecting element may also respectively have a through-hole for each electrical plug-in connection, in particular for each high-frequency plug-in connection, between the two printed circuit boards. Each electrical plug-in connection respectively electrically connects the two printed circuit boards to one another.

Instead of a metal plate having through-holes for each electrical plug-in connection, it is also possible to alternatively provide a plurality of metal sleeves which are arranged between the two printed circuit boards and electrically connect the two printed circuit boards, preferably ground contact surfaces of the two printed circuit boards. An electrical plug-in connection is respectively arranged between the two printed circuit boards in each metal sleeve.

According to the invention, the individual electrical plug-in connection has an electrical plug-in connector and an electrical mating plug-in connector.

The plug-in connector of the printed circuit board arrangement contains a contact element, preferably precisely one contact element, which is electrically and mechanically connected to the first printed circuit board at one end, which is referred to as the second end of the contact element below. The electrical and mechanical connection between the second end of the contact element and the first printed circuit board is preferably effected using a materially bonded connection, for example a soldered connection. Alternatively, a force-fitting connection, for example a press fit, or a form-fitting connection may also be implemented.

The mating plug-in connector of the printed circuit board arrangement has a contact body comprising a plurality of contact regions which are electrically connected to one another and are each deformable. The contact body is electrically and mechanically connected to the second printed circuit board at its second end. The contact body is preferably connected to the second printed circuit board via a materially bonded connection, that is to say via a soldered connection, in particular.

Alternatively or additionally, the contact body may also be encased in a housing which is connected to the second printed circuit board. The shape and the size of the housing are adapted to the shape and the size of the contact body. In order to enable contact to be made between the contact element and the contact body to the extent of the axial offset to be achieved between the two printed circuit boards, the housing has an accordingly designed opening in the region of the first end of the contact body. The contact body makes contact with an associated contact surface of the second printed circuit board with a sufficient contact pressure via the encasement of the contact body in the housing.

With regard to the electrical contact and the mechanical connection between the contact element of the plug-in connector and the contact body of the mating plug-in connector, reference is made to the explanations of the electrical plug-in connection according to the invention which were stated further above in this regard.

The electrical insulation between the rigid connecting element used as the outer conductor connection and the inner conductor connection composed of the contact element and the contact body is preferably effected by means of a suitably dimensioned air gap between the inner wall of the through-hole provided in the rigid connecting element and the outer contour of the inner conductor connection composed of the contact element and the contact body. As an alternative to the air gap, a suitably dimensioned sleeve which is made from a dielectric material and is arranged between the inner wall of the through-hole and the outer contour of the inner conductor connection is also conceivable.

The above configurations and developments can be combined with one another as desired if appropriate. Further possible configurations, developments and implementations of the invention also comprise combinations, not explicitly mentioned, of features of the invention described above or below with respect to the exemplary embodiments. In particular, a person skilled in the art will also add individual aspects as improvements or additions to the respective basic form of the present invention.

### INDICATION OF CONTENTS OF THE DRAWING

The present invention is explained in more detail below on the basis of the exemplary embodiments indicated in the schematic figures of the drawing, in which:

FIG. 1A shows a plan view of contact between a contact element and a contact body according to the prior art,

FIG. 1B shows a plan view of contact according to the invention between a contact element and a contact body,

FIGS. 2A, 2B, 2C, 2D and 2E show various illustrations of a first exemplary embodiment of an electrical plug-in connection according to the invention and a printed circuit board arrangement according to the invention,

FIGS. 3A and 3B show various illustrations of a second exemplary embodiment of an electrical plug-in connection according to the invention and a printed circuit board arrangement according to the invention,

FIGS. 4A and 4B show various illustrations of a third exemplary embodiment of an electrical plug-in connection according to the invention and a printed circuit board arrangement according to the invention,

FIGS. 5A and 5B show various illustrations of a fourth exemplary embodiment of an electrical plug-in connection according to the invention and a printed circuit board arrangement according to the invention, and

FIGS. 6A and 6B show various illustrations of a fifth exemplary embodiment of an electrical plug-in connection according to the invention and a printed circuit board arrangement according to the invention.

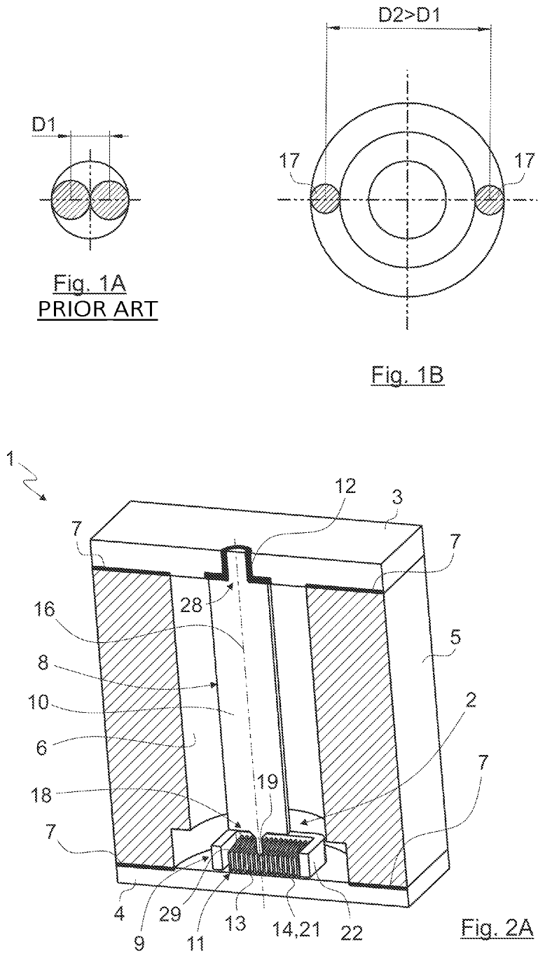

The accompanying figures of the drawing are intended to convey a better understanding of the exemplary embodiments of the invention. They illustrate exemplary embodiments and are used, in conjunction with the description, to explain principles and concepts of the invention. Other exemplary embodiments and many of the advantages mentioned are apparent with regard to the drawings. The elements in the drawings are not necessarily shown in a manner true to scale with respect to one another.

In the figures of the drawing, identical, functionally identical and identically acting elements, features and components are each provided with the same reference signs—unless stated otherwise.

The figures are described in an interrelated and comprehensive manner below.

### DESCRIPTION OF EXEMPLARY EMBODIMENTS

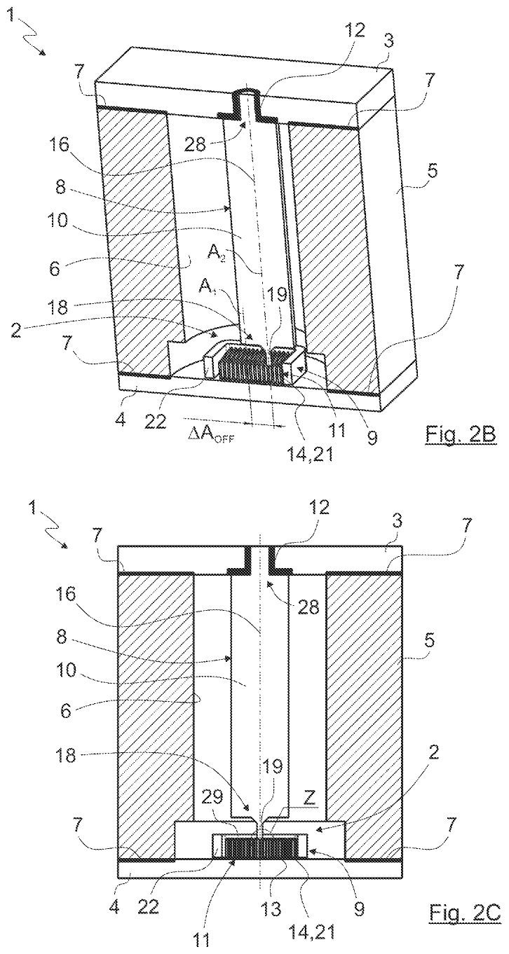

A first exemplary embodiment of a printed circuit board arrangement 1 according to the invention and of an electrical plug-in connection 2 according to the invention is explained in detail below with reference to FIGS. 2A to 2E:

The printed circuit board arrangement 1 according to the invention has at least one first printed circuit board 3 and one second printed circuit board 4. The at least two printed circuit boards 3, 4 are arranged parallel to one another at least within the scope of the manufacturing and installation tolerances and are each populated with electronic components, integrated circuits and further mechanical, optical and acoustic components at least on one surface. The individual printed circuit boards carry, in particular, high-frequency components and high-frequency circuits.

In order to electrically connect the individual high-frequency components and high-frequency circuits on the first printed circuit board 3 and on the second printed circuit board 4 to one another, at least one high-frequency connection is arranged between the first printed circuit board 3 and the second printed circuit board 4. Ira this case, the high-frequency connection is implemented via a rigid connecting element 5 and an electrical plug-in connection 2 which is arranged in a through-hole 6 of the rigid connecting element 5.

The rigid connecting element 5 is preferably produced from a metal and is therefore electrically conductive. The rigid connecting element 5 is connected to a common reference potential, preferably a ground potential, of the first printed circuit board 3 and of the second printed circuit board 4 via contact surfaces 7 which are formed on associated contact areas of the first printed circuit board 3 and of the second printed circuit board 4. The rigid connecting element 5 is therefore used as an outer conductor or shield of the high-frequency connection.

The electrical plug-in connection 2 according to the invention, which has a plug-in connector 8 electrically and mechanically connected to the first printed circuit board 3 and a mating plug-in connector 9 electrically and mechanically connected to the second printed circuit board 4, is used as the inner conductor of the high-frequency connection. The plug-in connector 8 is in the form of a pin-shaped contact element 10 and the mating plug-in connector 9 is in the form of a complex structured contact body 11.

At its second end 28, that is to say at its longitudinal-side end directed toward the first printed circuit board 3, the contact element 10 is electrically and mechanically connected to an associated contact surface 12 on the first printed circuit board 3 via a materially bonded connection, preferably a soldered connection. In an equivalent manner, at its second end 13, that is to say at its longitudinal-side end directed toward the second printed circuit board 4, the contact body 11 is connected in a materially bonded manner to an associated contact surface 12 on the second printed circuit board 4 (see, in this respect, FIG. 2D, in particular).

In the plugged state of the electrical plug-in connection 2, the contact element 10 makes electrical contact with the contact body 11. At the same time, the contact element 10 is mechanically connected to the contact body 11. For the mechanical and electrical connection between the contact element 10 and the contact body 11, the contact body 11 contains a plurality of contact regions 14 which are electrically connected to one another and are each deformable. The individual contact regions 14 are arranged in the contact body 11 with respect to one another in such a manner that individual intermediate spaces 15 run in the direction of the longitudinal axis 16 of the contact element 10 in the contact body 11 between individual contact regions 14, as is clear from FIG. 2E, in particular. These intermediate spaces 15 may be in the form of slots, openings, holes and the like. These intermediate spaces 15 are each open at least at the first end 29 of the contact body 11, that is to say at that end of the contact body 11 which is directed toward the contact element 10 and the plug-in connector 8. The contact element 10 can therefore be inserted into the insertion region 17 inside the intermediate space 15 of the contact body 11.

Each insertion region 17 inside an intermediate space 15 is bounded by at least two contact regions 14 of the contact body 11, with the result that, when a contact element 10 is inserted in the insertion region 17, electrical contact is made between the contact element 10 and the contact body 11. In addition, the contact regions 14 adjoining the insertion region 17 are deformed by the inserted contact element 10 in such a manner that a contact pressure sufficient for a mechanical connection is built up between the contact element 10 and the adjoining contact regions 14 of the contact body 11.

In order to make contact with the contact body 11, the contact element 10 has, at its first end 18, that is to say at the longitudinal-side end directed toward the mating plug-in connector 9 and the contact body 11, a first longitudinal portion 19 which has a constant diameter. This constant diameter of the first longitudinal portion 19 is such that the contact element 10 can be inserted, by way of its first longitudinal portion 19, into the individual intermediate spaces 15 of the contact body 11 and, at the same time, a sufficient contact pressure with respect to the adjoining contact regions 14 of the contact body 11 can be built up.

A second longitudinal portion 20, which is preferably in the form of a conical tip, preferably adjoins the first longitudinal portion 19 at the first end 18 of the contact element 10. This tip formed in the second longitudinal portion 20 makes it possible to insert the contact element 10 more easily into the individual intermediate spaces 15 of the contact body 11. In particular, if the second longitudinal portion 20 of the contact element impinges on the end surface of the individual contact regions 14 of the contact body 11, the tip of the contact element 10 makes it possible to insert the contact element 10 into the closest intermediate space of the contact body 11.

As an alternative or in addition to the conical second longitudinal portion 20 of the contact element 10, the individual contact regions 14 of the contact body 11 may have a conical cross-sectional profile at the first end 29 of the contact body 11, as indicated in FIG. 2E.

As a result of the contact body 11 being formed from a plurality of contact regions 14 and a plurality of intermediate spaces 15 arranged in between, it is possible to achieve electrical contact between the contact element 10 and the contact body 11 even in the case of a relatively large axial offset between the first printed circuit board 3 and the second printed circuit board 4. If there is no axial offset between the first printed circuit board 3 and the second printed circuit board 4, the longitudinal axis 16 of the contact element 10 is along the axis A₁ indicated in FIG. 2B. In the case of an axial offset ΔA_{OFF}, the longitudinal axis 16 of the contact element 10 comes to lie along the axis A₂ indicated in FIG. 26. The contact body 11 has a sufficient extent in a direction orthogonal to the longitudinal axis 16 of the contact element 10 to bridge a corresponding axial offset ΔA_{OFF} between the two printed circuit boards while maintaining the contact between the contact element 10 and the contact body 11.

In a first exemplary embodiment of an electrical plug-in connection 2 according to FIGS. 2A to 2E, the contact body 11 has individual contact lamellae 21 which are arranged parallel to one another, intermediate spaces for inserting the contact element 10 are respectively formed between the individual contact lamellae 21. The individual contact lamellae 21 each have a sufficient lateral extent to accommodate the first longitudinal portion 19 and the second longitudinal portion 20 of the contact element 10 in the intermediate spaces 15. In this manner, electrical contact between the contact element 10 and the contact body 11 is ensured, on the one hand, and a deviation in the distance between the two printed circuit boards 3, 4 can be compensated for, on the other hand.

In the region of the second end 13 of the contact body 11, the longitudinal-side ends of the individual contact lamellae 21 are connected in a materially bonded manner to contact surfaces 12 on the second printed circuit board 4. The longitudinal-side ends of the individual contact lamellae 21 are encased in a housing 22 which is connected to the second printed circuit board 4. In order to enable contact to be made between the contact element 10 and the contact body 11, the housing 22 has a sufficiently dimensioned opening at the first end 29 of the contact body 11.

When explaining the now following further exemplary embodiments of an electrical plug-in connection 2, there is no longer a repeated description of features which are identical to the first exemplary embodiment.

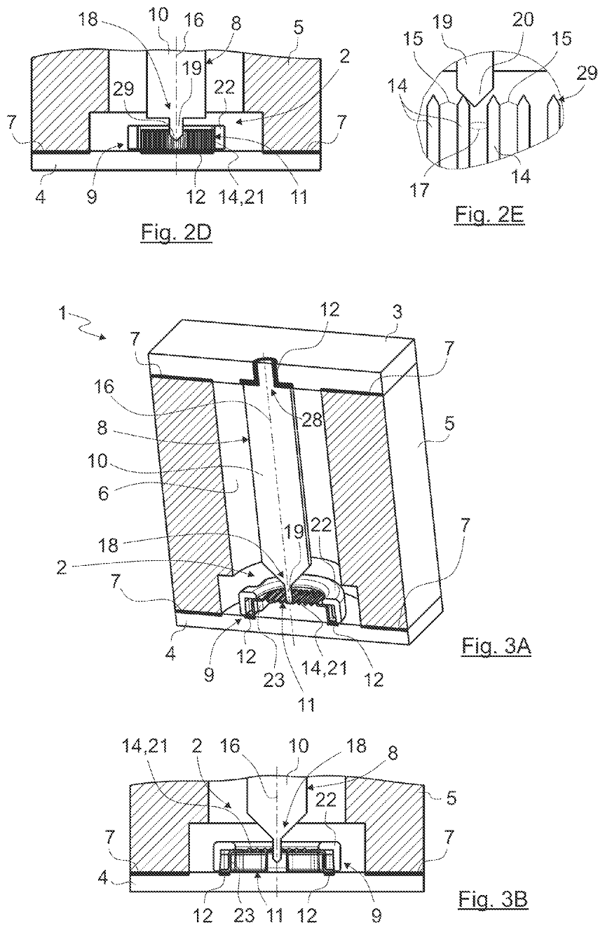

In a second exemplary embodiment of an electrical plug-in connection 2 according to FIGS. 3A and 3B, the individual contact lamellae 21 arranged parallel to one another are connected, at their longitudinal-side ends, to a contact frame 23 belonging to the contact body 11. The individual contact lamellae 21 are preferably connected to the contact frame 23 via so-called “film hinges”, that is to say narrow junctions, in order to preferably enable simple deformability of the individual contact lamellae 21 when inserting the contact element 10. The contact frame 23 is likewise encased in a housing 22 which is connected to the second printed circuit board 4.

The contact frame 23 may be pressed onto contact surfaces 12 of the second printed circuit board 4 via the housing 22 and may therefore achieve electrical contact between the contact body 11 and the contact surfaces 12. Alternatively, the contact frame 23 of the contact body 11 may be connected in a materially bonded manner to the contact surfaces 12 of the second printed circuit board 4.

The contact frame 23 may preferably have a circular cross-sectional profile, as indicated in FIGS. 3A and 3B. However, other cross-sectional profiles, for example a square cross-sectional profile, are also conceivable.

The width of the individual contact lamellae 21 in the second exemplary embodiment according to FIGS. 3A and 3B is reduced in comparison with the width of the individual contact lamellae 21 in the first exemplary embodiment. In the second exemplary embodiment, the individual contact lamellae 21 are connected to the contact frame 23 at an elevated position in comparison with the base of the contact frame 23, at which the contact frame 23 makes contact with the contact surfaces 12 of the second printed circuit board 4. A sufficient clearance for inserting the contact element 10 into the contact body 11 is therefore located below the individual contact lamellae 21 up to the second printed circuit board 4. This makes it possible to bridge a sufficiently large deviation in the distance between the two printed circuit boards 3, 4.

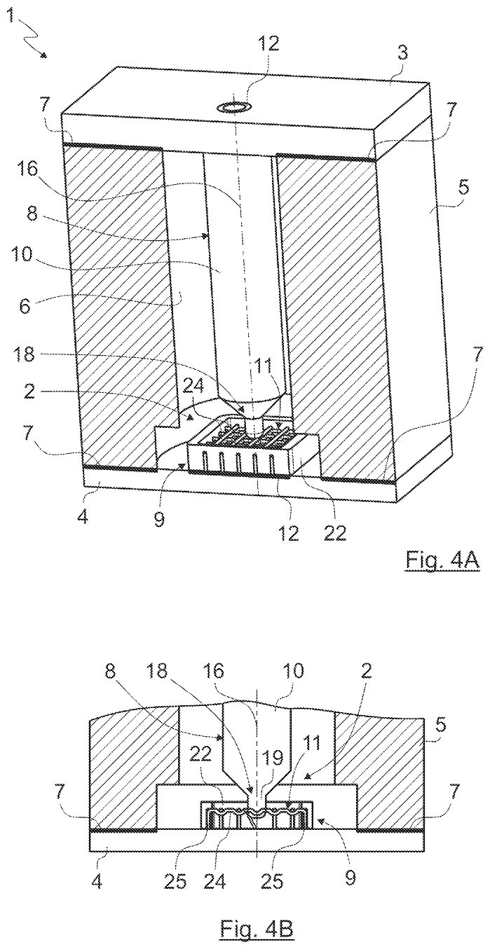

In a third exemplary embodiment of the electrical plug-in connection 2 according to FIGS. 4A and 4B, the contact body 11 is composed of individual contact wires 24 which are arranged in the form of a grid with respect to one another. Instead of contact wires 24, contact bars arranged in the form of a grid are also possible. The grid-shaped arrangement of the contact wires 24 results in square or rhombic intermediate 40 spaces in which insertion regions 17 for the contact element 10 are possible.

The individual contact wires 24 are likewise fastened in a housing 22. In analogy to the second exemplary embodiment, the individual contact wires 24 are at an elevated position in comparison with the contact surfaces 12 of the second printed circuit board 4 in order to enable a sufficient clearance between the individual contact wires 24 and the second printed circuit board 4 for the purpose of inserting the contact element 10. This likewise makes it possible to bridge a certain deviation of the two printed circuit boards 3, 4 from a target deviation.

In order to achieve the elevated arrangement of the individual contact wires 24 with respect to the second printed circuit board 4, the individual contact wires 24 arranged in the form of a grid are connected to a contact frame 23 at a particular height. This contact frame 23 may likewise be encased in a housing 22 in order to exert a sufficient contact pressure on contact surfaces 12 of the second printed circuit board 4 via the housing 22. Alternatively, the contact frame 23 may also be connected in a materially bonded manner to the contact surfaces 12 of the second printed circuit board 4.

Finally, it is also possible to bend each of the individual contact wires 24 through 90° at a particular distance from the two longitudinal ends in order to use the bent ends to respectively achieve contact feet of the same length. These contact feet 25 of the individual contact wires 24 are preferably fixed inside a housing 22 and may be connected in a materially bonded manner to contact surfaces 12 of the second printed circuit board 4.

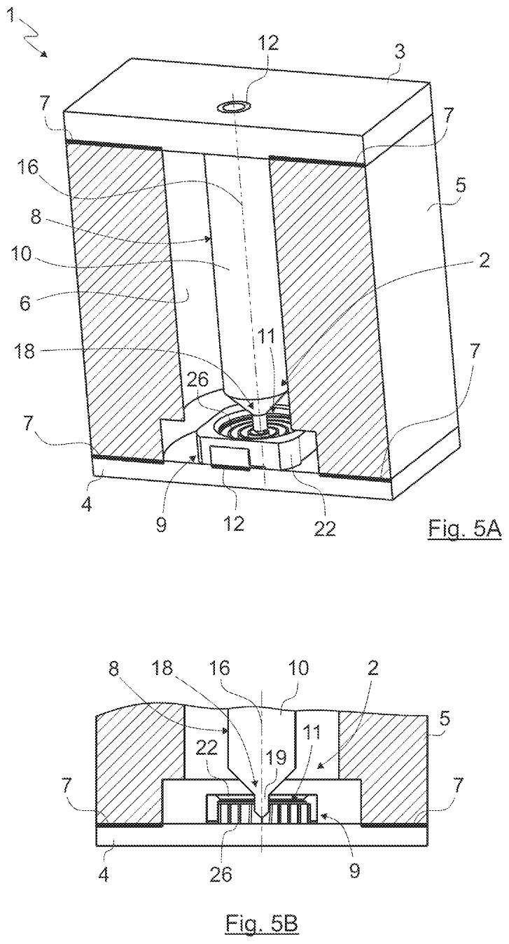

In a fourth exemplary embodiment of the electrical plug-in connection 2 according to FIGS. 5A and 5B, a spiral contact lamella 26, which is arranged in a plane orthogonal to the longitudinal axis 16 of the contact element 10 is used as the contact body 11. The spiral contact lamella 26 provides contact regions 14 for making contact with the contact element 10 along its longitudinal extent. An intermediate space 15 which provides a plurality of insertion regions 17 for the contact element 10 is located between the individual contact regions 14 of the spiral contact lamella 26. The spiral of the contact lamella 26 is shaped in such a manner that a sufficient intermediate space 15 is present between the individual contact regions 14 of the spiral contact lamella 26 for inserting the contact element 10 and for the force-fitting connection between the contact element 10 and the adjoining contact regions 14.

The spiral contact lamella 26 is likewise encased in a housing 22. In order to achieve deformability of the spiral contact lamella 26 over its entire longitudinal extent, only the longitudinal-side end of the spiral contact lamella 26, which is located at the outermost end of the spiral, that is to say at that longitudinal-side end of the spiral which is located in the housing 22, is connected in a materially bonded manner to a contact surface 12 of the second printed circuit board 4. The width of the spiral contact lamella 26 is such that it is possible to insert and therefore make contact with the contact element 10 in the spiral contact body 11 for certain deviations in the distance between the two printed circuit boards.

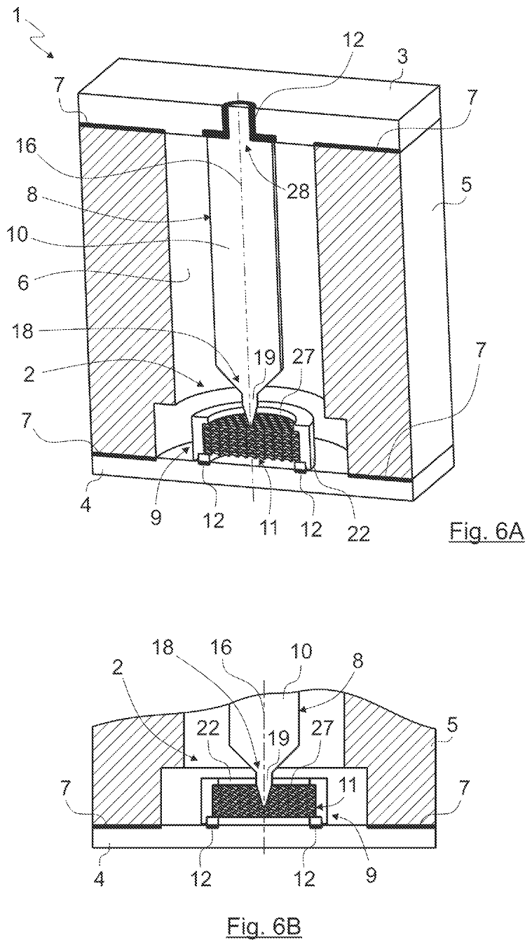

In a fifth exemplary embodiment of the electrical plug-in connection 2 according to FIGS. 6A and 66, the contact body 11 is in the form of a three-dimensionally braided wire mesh 27, in this case, the wire mesh 27 is preferably braided in a completely irregular manner. However, a regular three-dimensional mesh structure for the wire mesh 27 is also conceivable. The three-dimensional wire mesh 27 may preferably be pressed into a particular shape and a particular size. The shape into which the three-dimensional wire mesh 27 is preferably pressed may preferably be cylindrical. However, a cuboid shape or any other useful shape is also conceivable.

On account of the “comparatively loose structure” of the three-dimensional wire mesh 27, insertion regions 17 for the contact element 10 can be formed, even in the pressed state, between the wires of the wire mesh 27 which are used as contact regions 14. Inserting the contact element 10 into an insertion region 17 of the wire mesh 27 typically displaces wires of the wire mesh 27. The displacement and the associated deformation of these wires of the wire mesh 27 results in a sufficient contact pressure of the wires of the wire mesh 27 on the contact element 10 and therefore in a reliable electrical and mechanical connection between the contact element 10 and the contact body 11. A reliable electrical and mechanical connection between the contact element 10 and the three-dimensional wire mesh 27 used as the contact body 11 can be achieved by suitably designing the wire diameter.

The preferably pressed three-dimensional wire mesh 27 is likewise encased in a housing 22. A sufficient contact pressure between the wire mesh 27 and the contact surfaces 12 of the second printed circuit board 4 is exerted via the housing 22, with the result that reliable electrical contact is achieved between the three-dimensional wire mesh 27 used as the contact body 11 and the contact surfaces 12 of the second printed circuit board 4.

Although the present invention has been described completely above on the basis of preferred exemplary embodiments, it is not restricted thereto, but rather can be modified in various ways.

1. An electrical plug-in connection comprising a plug-in connector and a mating plug-in connector,
wherein the plug-in connector includes a contact element, wherein the mating plug-in connector includes a contact body comprising a plurality of contact regions which are electrically connected to one another and are each deformable,
wherein contact regions of the plurality of contact regions are arranged with respect to one another in such a manner that a plurality of different insertion regions for inserting the contact element into the contact body are present in the contact body,
wherein one contact region of the plurality of contact regions is respectively arranged between at least two of the insertion regions in the contact body in at least one direction which runs orthogonally to a longitudinal axis of the contact element, and
wherein each contact region of the plurality of contact regions respectively adjoining a respective insertion region is deformed by the contact element inserted in the respective insertion region in such a manner that an electrical contact and a mechanical connection can be established between the plug-in connector and the mating plug-in connector.

2. The electrical plug-in connection as claimed in claim 1, wherein each contact region of the plurality of contact regions adjoining the respective insertion region forms at least one of a contact surface, a contact line, or both with the contact element.

3. The electrical plug-in connection as claimed in claim 1, wherein each contact region of the plurality of contact regions is deformed in such a manner that an elastic restoring force s established in each contact region of the plurality of the contact regions exerts a contact pressure on the contact element.

4. The electrical plug-in connection as claimed in claim 1,
wherein the plurality of contact regions has, in a direction orthogonal to the longitudinal axis of the contact element, an extent which is less than an extent of the contact element in the direction orthogonal to the longitudinal axis of the contact element.

5. The electrical plug-in connection as claimed in claim 1,
wherein the contact element comprises a first longitudinal portion which has a constant diameter at a first end of the contact element directed toward the mating plug-in connector, the first longitudinal portion making contact with the contact regions of the plurality of contact regions adjoining the respective insertion region.

6. The electrical plug-in connection as claimed in claim 5, wherein the contact element comprises a second longitudinal portion which is located between the first longitudinal portion and the first end of the contact element, and wherein the second longitudinal portion has a diameter tapering to the first end of the contact element.

7. The electrical plug-in connection as claimed in claim 6, wherein the longitudinal extent of each insertion region that is formed in the contact body respectively corresponds at least to the longitudinal extent of (i) the first longitudinal portion of the contact element or (ii) the first longitudinal portion and the second longitudinal portion of the contact element.

8. The electrical plug-in connection as claimed in claim 5,
wherein depending on an axial distance between the plug-in connector and the mating plug-in connector, a section of the first longitudinal portion of the contact element contacts the contact body with a respective axial length or in a respective axial position inside the first longitudinal portion of the contact element.

9. The electrical plug-in connection as claimed in claim 1,
wherein each contact region of the plurality of contact regions has, in a first cross-sectional portion at a first end of the contact body that is directed toward the plug-in connector, a cross-sectional profile tapering to the first end of the contact body.

10. The electrical plug-in connection as claimed in claim 1,
wherein individual contact regions of the plurality of contact regions are arranged inside the contact body in a regular structure with respect to one another.

11. The electrical plug-in connection as claimed in claim 10,
wherein individual contact regions of the plurality of contact regions are arranged along (i) a plurality of contact lamellae arranged in a parallel manner and spaced apart from one another by an intermediate space or (ii) a plurality of contact wires arranged in a crossed manner with respect to one another and spaced apart from one another.

12. The electrical plug-in connection as claimed in claim 1,
wherein the plurality of contact regions is arranged along at least one bent contact lamella.

13. The electrical plug-in connection as claimed claim 1,
wherein individual contact regions of the plurality of contact regions are arranged with respect to one another inside the contact body in an irregular structure.

14. A printed circuit board arrangement [(1)] comprising
a first printed circuit board;
a second printed circuit board; and
an electrical plug-in connection comprising a plug-in connector and a mating plug-in connector,
wherein the plug-in connector includes a contact element, and
wherein the mating plug-in connector includes a contact body comprising a plurality of contact regions which are electrically connected to one another and are each deformable,
wherein contact regions of the plurality of contact regions are arranged with respect to one another in such a manner that a plurality of different insertion regions for inserting the contact element into the contact body are present in the contact body,
wherein one contact region of the plurality of contact regions is respectively arranged between at least two of the insertion regions in the contact body in at least one direction which runs orthogonally to a longitudinal axis of the contact element, and
wherein each contact region of the plurality of contact regions respectively adjoining a respective insertion region is deformed by the contact element inserted in the respective insertion region in such a manner that an electrical contact and a mechanical connection can be established between the plug-in connector and the mating plug-in connector;
wherein the first and second printed circuit boards are arranged in a manner running in different planes with respect to one another, and
wherein the electrical plug-in connection respectively electrically connects the first and second printed circuit boards to one another,
wherein the contact element is electrically and mechanically connected to the first printed circuit board, and
wherein the contact body is electrically and mechanically connected to the second printed circuit board.

15. The printed circuit board arrangement as claimed in claim 14,
further comprising a rigid connecting element arranged between the first and second printed circuit boards and electrically connecting the first printed circuit board and the second printed circuit board to one another, wherein the rigid connecting element encases the electrical plug-in connection in an associated through-hole.

16. The printed circuit board arrangement as claimed in claim 14,
wherein the contact body is enclosed in a housing which is connected to the second printed circuit board and which has an opening for making a contact between the contact element and the contact body.

17. The printed circuit board arrangement as claimed in claim 14, wherein each contact region of the plurality of contact regions adjoining the respective insertion region forms at least one of a contact surface, a contact line, or both with the contact element.

18. The printed circuit board arrangement as claimed in claim 14, wherein each contact region of the plurality of contact regions is deformed in such a manner that an elastic restoring force, established in each contact region of the plurality of the contact regions, exerts a contact pressure on the contact element.

19. The printed circuit board arrangement as claimed in claim 14, wherein the plurality of contact regions has, in a direction orthogonal to the longitudinal axis of the contact element, an extent which is less than an extent of the contact element in the direction orthogonal to the longitudinal axis of the contact element.

20. The printed circuit board arrangement as claimed in claim 14, wherein the contact element comprises a first longitudinal portion which has a constant diameter at a first end of the contact element directed toward the mating plug-in connector, the first longitudinal portion making contact with the contact regions of the plurality of contact regions adjoining the respective insertion region.
